(19) United States
(12) Patent Application Publication
(10) Pub. No.: US 2025/0237959 A1
(43) Pub. Date: Jul. 24, 2025

(54) PLASMA MULTI-WAFER ASHING SYSTEM

(71) Applicant: Rockwell Collins, Inc., Cedar Rapids, IA (US)

(72) Inventors: Mark J. Reimer, Coralville, IA (US); Kyle J. Pierson, Ely, IA (US)

(21) Appl. No.: 18/417,549

(22) Filed: Jan. 19, 2024

(51) Int. Cl. G03F 7/42; H01J 37/32

(52) U.S. Cl. CPC G03F 7/427; H01J 37/32449; H01J 37/32467; H01J 37/32724; H01J 2237/3342

(57) ABSTRACT

A system for ashing is disclosed. The system may include a chamber that includes an inlet for receiving the medium into the chamber and an outlet for expelling the medium. The system may also include a first diffuser plate positioned between the first volume and the second volume and configured to split the medium received from the inlet into one or more pathways. A second diffuser plate may be positioned between the second volume and the third volume, configured to allow selective transfer of the medium along the one or more pathways to the substrate. The system may further include a support structure within the third volume and coupled to the chamber, and a gapped airflow modulator configured to modulate a flow of the medium.

### GOVERNMENT SUPPORT

This invention was made with government support under Contract Number FA8650-21-C-7005, awarded by the U.S. Air Force. The government has certain rights in this invention.

### TECHNICAL FIELD

The present disclosure relates generally to semiconductor manufacturing and, more specifically, to systems and methods for processing substrates.

### BACKGROUND

The process of creating an integrated circuit on a semiconductor substrate may involve the arrangement of a photoresist film with a circuit pattern on the surface of the semiconductor substrate. Subsequently, layers beneath the photoresist film, such as an insulation film, a semiconductor film, or a metal film, undergo etching through the photoresist film. Upon completion of the etching process, the photoresist film may be removed from the substrate surface. One method for the removal of the photoresist film includes a dry processing technique involving ashing (incineration), which may utilize plasma generated from a reactive gas, such as oxygen plasma.

### SUMMARY

A system for ashing is disclosed in accordance with one or more illustrative embodiments of the present disclosure. In one illustrative embodiment, the system may include a chamber configured to enclose a substrate within a volume of the chamber and to process the substrate via a medium. In another illustrative embodiment, the volume may include a first volume, a second volume, and a third volume, where the first volume is above the second volume and the second volume is above the third volume. In another illustrative embodiment, the chamber may include an inlet configured for receiving the medium into the chamber, where the inlet is in fluid communication with the first volume. In another illustrative embodiment, the chamber may include an outlet for expelling the medium after it has interacted with the substrate, where the outlet is in fluid communication with the third volume.

In another illustrative embodiment, a first diffuser plate may be positioned between the first volume and the second volume and configured to split the medium received from the inlet into one or more pathways as it passes from the first volume to the second volume. The first diffuser plate may be configured to allow selective transfer of the medium to the one or more pathways via one or more sets of first passthrough voids, each associated with a particular substrate and a respective set of first passthrough voids. In another illustrative embodiment, a second diffuser plate may be positioned between the second volume and the third volume, configured to allow selective transfer of the medium along the one or more pathways to the substrate via one or more sets of second passthrough voids, each set of second passthrough voids being aligned with the respective set of first passthrough voids and a respective substrate to facilitate targeted delivery of the medium to the substrate.

In another illustrative embodiment, a support structure within the third volume and coupled to the chamber may include one or more protrusions extending from a lower surface towards the second diffuser plate, each protrusion configured for holding a single substrate. In another illustrative embodiment, a gapped airflow modulator configured to modulate a flow of the medium may be disposed between the one or more protrusions and lower than the substrate such that the gapped airflow modulator is further from the second diffuser plate than the substrate. The gapped airflow modulator may be spaced away from the one or more protrusions via a first set of gaps and spaced above the lower surface via a second gap.

In a further aspect, the system may be configured for two or more substrates such that the one or more pathways include two or more pathways, the one or more sets of first passthrough voids include two or more sets of first passthrough voids, the one or more sets of second passthrough voids include two or more sets of second passthrough voids, and the one or more protrusions include two or more protrusions. In another aspect, the gapped airflow modulator may include a plate defining circular voids, where the first set of gaps are defined as being between the circular voids and the protrusions. In another aspect, the one or more sets of first passthrough voids may be larger in diameter than the one or more sets of second passthrough voids. In another aspect, the one or more protrusions may include four protrusions configured to hold four substrates. In another aspect, the support structure may be removably couplable to the chamber. In another aspect, the chamber, the support structure, and the gapped airflow modulator may include aluminum. In another aspect, the protrusions may enclose an internal reservoir configured to house temperature-controlling fluid for cooling the substrates via indirect thermal communication with the temperature-controlling fluid. In another aspect, each protrusion may include an elevated cylindrical platform. In another aspect, the medium may include ionized plasma. In another aspect, the first set of gaps may be 0.009 inches or more. In another aspect, the second gap may be 0.02 inches or more. In another aspect, the first set of gaps may be 0.1 inches or more. In another aspect, the second gap may be 0.2 inches or more.

A method for ashing is disclosed in accordance with one or more illustrative embodiments of the present disclosure. In one illustrative embodiment, the method may include enclosing substrates within a volume of a chamber, where the volume includes a first volume, a second volume, and a third volume. In another illustrative embodiment, the first volume is above the second volume, and the second volume is above the third volume. In another illustrative embodiment, the method may include receiving a medium into the chamber through an inlet in fluid communication with the first volume. In another illustrative embodiment, the method may include positioning a first diffuser plate between the first volume and the second volume to split the medium received from the inlet into two or more pathways as it passes from the first volume to the second volume. In another illustrative embodiment, the first diffuser plate allows selective transfer of the medium to the two or more pathways via two or more sets of first passthrough voids, each pathway associated with a particular substrate and a respective set of first passthrough voids. In another illustrative embodiment, the method may include positioning a second diffuser plate between the second volume and the third volume to allow selective transfer of the medium along the two or more pathways to the substrates via two or more sets of second passthrough voids, each set of second passthrough voids being aligned with the respective set of first passthrough voids and a respective substrate to facilitate targeted delivery of the medium to the substrates. In another illustrative embodiment, the method may include providing a support structure within the third volume and coupled to the chamber, where the support structure includes two or more protrusions extending from a lower surface towards the second diffuser plate, each protrusion configured for holding a single substrate. In another illustrative embodiment, the method may include modulating a flow of the medium with a gapped airflow modulator disposed between the two or more protrusions and lower than the substrates such that the gapped airflow modulator is further from the second diffuser plate than the substrates, where the gapped airflow modulator is spaced away from the two or more protrusions via a first set of gaps, and spaced above the lower surface via a second gap. In another illustrative embodiment, the method may include expelling the medium after interaction with the substrates through an outlet in fluid communication with the third volume.

In a further aspect, the gapped airflow modulator may include a plate defining circular voids, and the first set of gaps are defined as being between the circular voids and the protrusions. In another aspect, the two or more sets of first passthrough voids may be larger in diameter than the two or more sets of second passthrough voids. In another aspect, the two or more protrusions may include four protrusions configured to hold four substrates. In another aspect, the method may further include removably coupling the support structure to the chamber. In another aspect, the protrusions may enclose an internal reservoir configured to house temperature-controlling fluid for cooling the substrates via indirect thermal communication with the temperature-controlling fluid.

This Summary is provided solely as an introduction to subject matter that is fully described in the Detailed Description and Drawings. The Summary should not be considered to describe essential features nor be used to determine the scope of the Claims. Moreover, it is to be understood that both the foregoing Summary and the following Detailed Description are example and explanatory only and are not necessarily restrictive of the subject matter claimed.

### BRIEF DESCRIPTION OF THE DRAWINGS

The detailed description is described with reference to the accompanying figures. The use of the same reference numbers in different instances in the description and the figures may indicate similar or identical items. Various embodiments or examples (“examples”) of the present disclosure are disclosed in the following detailed description and the accompanying drawings. The drawings are not necessarily to scale. In general, operations of disclosed processes may be performed in an arbitrary order, unless otherwise provided in the claims.

FIG. 1 is a cross-sectional view of a system for ashing four substrates, in accordance with one or more embodiments of the present disclosure.

FIG. 2 is a cross-sectional view of the system with a small upper portion hidden for clarity, in accordance with one or more embodiments of the present disclosure.

FIG. 3 is a cross-sectional view of the system with a medium upper portion hidden for clarity, in accordance with one or more embodiments of the present disclosure.

FIG. 4 is a cross-sectional view of the system with a large upper portion hidden for clarity, in accordance with one or more embodiments of the present disclosure.

FIG. 5 is a cross-sectional view of the system including an outlet, in accordance with one or more embodiments of the present disclosure.

FIG. 6 is a diagonally cut cross-sectional view of the system with a portion enlarged showing gaps around the gapped airflow modulator, in accordance with one or more embodiments of the present disclosure.

FIG. 7 is a cross cut cross-sectional view of the system, in accordance with one or more embodiments of the present disclosure.

FIG. 8 is a method for ashing substrates, in accordance with one or more embodiments of the present disclosure.

### DETAILED DESCRIPTION

Before explaining one or more embodiments of the disclosure in detail, it is to be understood that the embodiments are not limited in their application to the details of construction and the arrangement of the components or steps or methodologies set forth in the following description or illustrated in the drawings. In the following detailed description of embodiments, numerous specific details may be set forth in order to provide a more thorough understanding of the disclosure. However, it will be apparent to one of ordinary skill in the art having the benefit of the instant disclosure that the embodiments disclosed herein may be practiced without some of these specific details. In other instances, well-known features may not be described in detail to avoid unnecessarily complicating the instant disclosure.

Broadly speaking, embodiments of concepts disclosed herein are directed to a system and method for efficiently and uniformly ashing wafers in a chamber using a series of staged diffuser plates to establish a uniform flow, complemented by an airflow modulation plate situated beneath the wafers to assist in maintaining the steadiness of the flow. Due to the improved uniformity in flow, the systems and methods herein may allow for processing multiple wafers simultaneously at relatively high yield rates. In embodiments, the system includes a uniformity of flow leaving the staged diffuser plates, multiple raised wafer platforms for allowing the air to flow past the wafers, and/or a gapped airflow modulator plate aiding in modulating the flow and keeping it uniform.

The airflow modulation plate may be gapped away from column platforms that support the wafers, allowing air flow paths that are less likely to reduce the uniformity. In embodiments, the plasma flow is separated into multiple pathways, one for each wafer, using multiple diffuser stages with decreasing hole sizes. In embodiments, the wafers are offset from the bottom of the chamber using elevated cooling platforms. In embodiments, an airflow modulator plate is positioned below the wafers, spaced away from the bottom and spaced away from the elevated platforms. It is contemplated herein that such an airflow modulator aides in affecting the flow of the plasma, such as reducing turbulence caused by the plasma pathways, which may otherwise affect the uniform application of the plasma medium to the wafers. The elevated platforms may be modular (i.e., for swapping out parts), such as being swappable for a configuration of a different number of wafers (e.g., a single large wafer, two wafers, four wafers, etc.).

The present disclosure outlines an approach that offers a dynamically adaptable and scalable solution, proficient at aligning with a spectrum of production volumes and specifications. The system may be designed to create more predictable and uniform ashing procedures across diverse production lines, while also accommodating variations in wafer size and quantity. Furthermore, the integration of an airflow modulator plate induces a more stable and/or laminar flow of reactive gas species, thereby enhancing the uniformity of the ashing effect across the entire surface of each semiconductor wafer. This reduction in process-induced anomalies may increase the proportion of defect-free wafers. In embodiments, a modular design of the elevated platforms confers upon the ashing chamber the ability for swift reconfiguration, which reduces downtime and bolsters the rate of production. By establishing a controlled environment for consistent ashing, the embodiments of the concepts disclosed herein can provide substantial advancements in semiconductor manufacturing, culminating in more streamlined production processes and superior quality devices.

In embodiments, the substrate may also be non-standard size and/or shapes. For example, rather than a circular shape, other substrates may be processed such as, but not limited to substrates in a rectangular shape, as a set of stacked chips, a triangle shape, an irregular shape, and/or any other substrates.

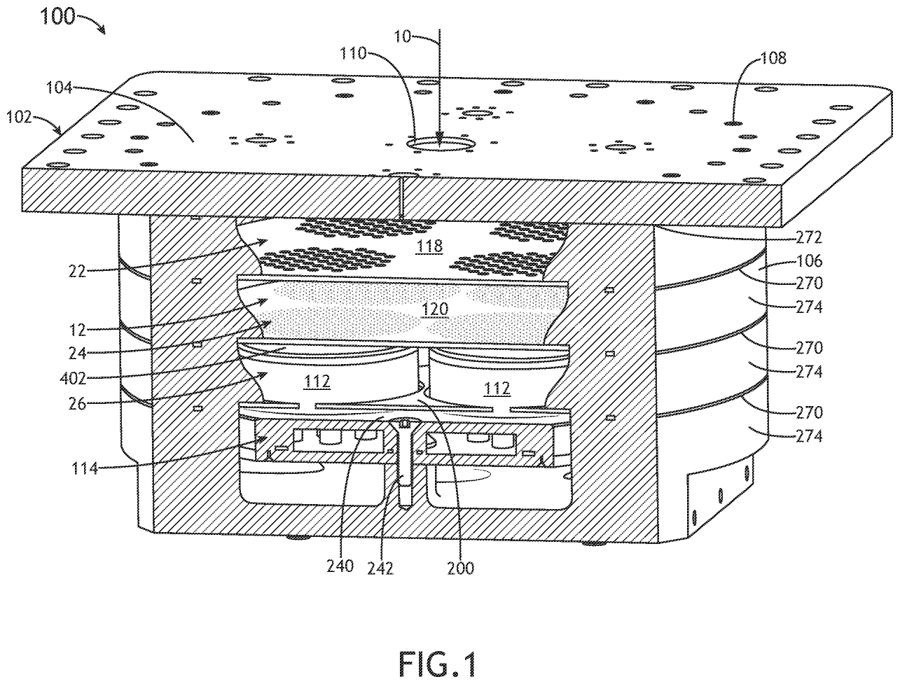

FIG. 1 illustrates a cross-sectional view of a system 100 for ashing four substrates 402, in accordance with one or more embodiments of the present disclosure. The front of the chamber 102 of the system 100 is hidden from view to see inside.

Note that even that the descriptions herein may describe the system 100 in terms of two or more pathways 116, two or more substrates 402, two or more protrusions 112, and/or the like, any number may be used. For example, unless otherwise noted, a single pathway 116, substrate 402, protrusion 112, and the like may be used in a single substrate 402 configuration.

A system 100 for ashing may include a chamber 102. The chamber 102 may be configured to enclose substrates 402 within a volume 12 and to process the substrates 402 via a medium 10 (e.g., ionized plasma). The system 100 may include a gapped airflow modulator 200 configured to modulate a flow of the medium 10. The medium 10 may include ionized plasma, as is used for ashing. For example, the medium 10 may be supplied to the inlet 110 using a plasma generator.

The volume 12 of the chamber 102 may include a first volume 22, a second volume 24, and a third volume 26. The first volume 22 may be positioned above the second volume 24, and the second volume 24 may be positioned above the third volume 26.

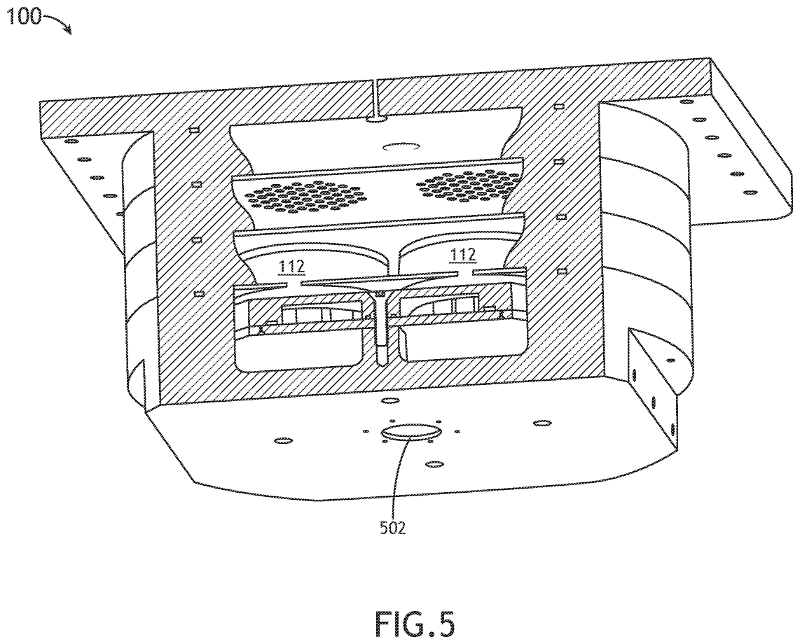

The chamber 102 may include an inlet 110 and an outlet 502 (see FIG. 5 for example outlet 502). The inlet 110 may be configured for receiving the medium 10 into the chamber 102 and may be in fluid communication with the first volume 22.

The outlet 502 may be in fluid communication with the third volume 26. The outlet 502 may be used for expelling the medium 10 after the medium 10 has interacted with the substrates 402. For example, the outlet 502 may be coupled to a vacuum pump (not shown) for expelling the medium 10 and assisting in moving the medium 10 along a pathway.

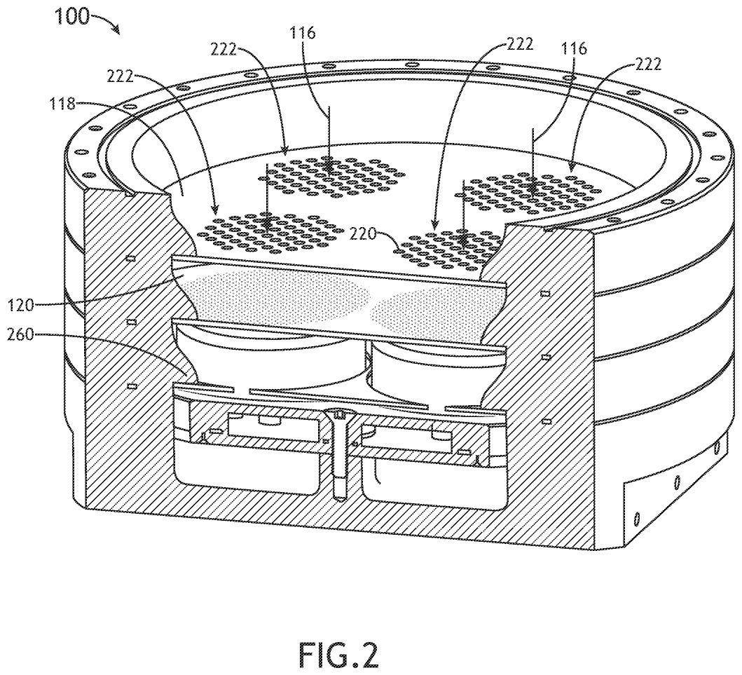

The system 100 may include a first diffuser plate 118 positioned between the first volume 22 and the second volume 24. In a sense, the first diffuser plate 118 may separate the first volume 22 and the second volume 24 and aide in creating a uniform set of flows (e.g., four pathways) of the medium 10 corresponding and aligned with the substrates 402. See FIG. 2 for example pathways 116.

For instance, the first diffuser plate 118 may be configured to split the medium 10 received from the inlet 110 into two or more pathways 116 (e.g., four or more pathways as shown in FIG. 2) as the medium 10 passes from the first volume 22 to the second volume 24. The first diffuser plate 118 may allow selective transfer of the medium 10 to the two or more pathways 116 via two or more sets of first passthrough voids 222. Each of the two or more pathways may be associated with a particular substrate 402 and a respective set of first passthrough voids 222.

For example, a particular, single set of first passthrough voids 222 may comprise a set of voids (e.g., holes 220 in a plate) arranged in a pattern (e.g., grid, circular-shaped array, and/or the like). For example, each void 220 may be circular or otherwise rotationally symmetrical, such as a star, pentagon, and/or the like. Each set of first passthrough voids 222 may be spaced from one another as shown, such as no voids being between the set of first passthrough voids 222, such that each set of first passthrough voids 222 creates a unique pathway 116 of a distinct flow of medium 10.

The system 100 may include a second diffuser plate 120 positioned between the second volume 24 and the third volume 26. The second diffuser plate 120 may be configured to allow selective transfer of the medium 10 along the two or more pathways to the substrates 402 via two or more sets of second passthrough voids 232. Each set of second passthrough voids 232 may be aligned (e.g., vertically aligned) with the respective set of first passthrough voids 222 and a respective substrate 402 to facilitate targeted delivery of the medium 10 to the substrates 402.

For purposes of the present disclosure, vertical means parallel to the pathways 116 and normal to the substrates 402 as shown in at least FIG. 2.

Within the third volume 26, a support structure 114 may be coupled to the chamber 102. For example, the support structure 114 may be removably couplable to the chamber 102, such as via being fastened via fasteners 242 (e.g., bolts, nuts, clamps, and/or the like).

The support structure 114 may include two or more protrusions 112 extending from a lower surface 240 towards the second diffuser plate 120. Each protrusion may be configured for holding a single substrate 402. Each protrusion 112 may include, and/or be coupled to a holder for holding the substrate 402 in place. For example, the holder may be tabs, clamps, recess for receiving the substrate 402, and/or the like.

In some embodiments, each protrusion 112 may include (and/or be) an elevated cylindrical platform. For example, being substantially cylindrical in shape as shown. The top of the platform may be configured to receive the substrates 402.

The gapped airflow modulator 200 may be disposed between the two or more protrusions 112 and lower than the substrates 402 such that the gapped airflow modulator 200 is further from the second diffuser plate 120 than the substrates 402. The gapped airflow modulator 200 may be spaced away from the two or more protrusions 112 via a first set of gaps 250, and spaced above the lower surface 240 via a second gap 252.

Note that the examples herein are nonlimiting and for illustrative purposes only and the system 100 may be configured for any number of substrates 402, any number of diffuser plates with corresponding volumes, and the like.

The chamber 102 may include a top surface 104. For example, the top surface 104 may be a surface of a top layer (e.g., top plate) of the chamber 102. The top surface 104 may define the inlet 110. The top surface 104 may include other voids, such as for other couplings. For instance, the other voids may be configured for being coupled/fastened to a plasma generator, intermediary plasma transfer system, and/or the like.

The chamber 102 may include side walls 106. For example, the side walls 106 may be vertically orientated. The side walls 106 may be circular when viewed from above.

The side wall 106 may include inward mounting surfaces 260. For instance, inward mounting surfaces 260 may be undercut as shown to allow fasteners (e.g., bolts) to fasten/mount elements to the inward mounting surfaces 260 from below or the like. For instance, the diffuser plates 118, 120, and the gapped airflow modulator 200 may be mounted to inward mounting surfaces 260.

The side wall 106 may include (and/or be) partitioned, such that each partition 274 is removably couplable to adjacent partitions. For example, the partition lines 270 may indicate where the side wall 106 is separable from itself. In some examples, the partition lines 270 corresponds to an inward mounting surfaces 260, such that the diffuser plates 118, 120, and the gapped airflow modulator 200 are able to be individually accessible, mountable, and/or replaceable. The partition lines 270 may also allow for loading and unloading substrates 402 for processing.

The top layer and top surface 104 may also be removably couplable from the side wall 106 at a secondary partition 272.

The partitions 274 and top surface 104 may be removably couplable using fasteners 108, such as (relatively long) fasteners (e.g., bolts) inserted vertically through the top surface 104, into the side wall 106, to simultaneously couple all partitions 274.

FIG. 2 illustrates a cross-sectional view of the system 100 with a small upper portion hidden for clarity via cutaway, in accordance with one or more embodiments of the present disclosure. In other words, there are two cutaways to show inside the chamber 102, one cutaway in the front, and one cutaway on top.

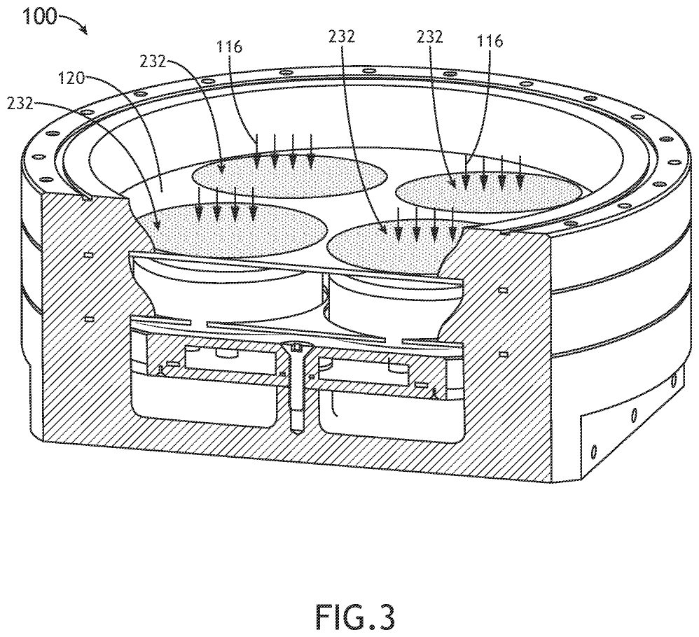

FIG. 3 illustrates a cross-sectional view of the system 100 with a medium upper portion hidden for clarity, in accordance with one or more embodiments of the present disclosure.

In some embodiments, the two or more sets of first passthrough voids 222 of the second diffuser plate 120 may be larger in diameter than the two or more sets of second passthrough voids 232. Using sequentially smaller and smaller holes may allow for more uniform and fine control of the flow of the medium 10.

For example, the two or more sets of first passthrough voids 222 may be at least 20% larger in diameter than the two or more sets of second passthrough voids 232. For example, the two or more sets of first passthrough voids 222 may be at least twice as large in diameter than the two or more sets of second passthrough voids 232. Diameter may mean total width if a non-circular void is used.

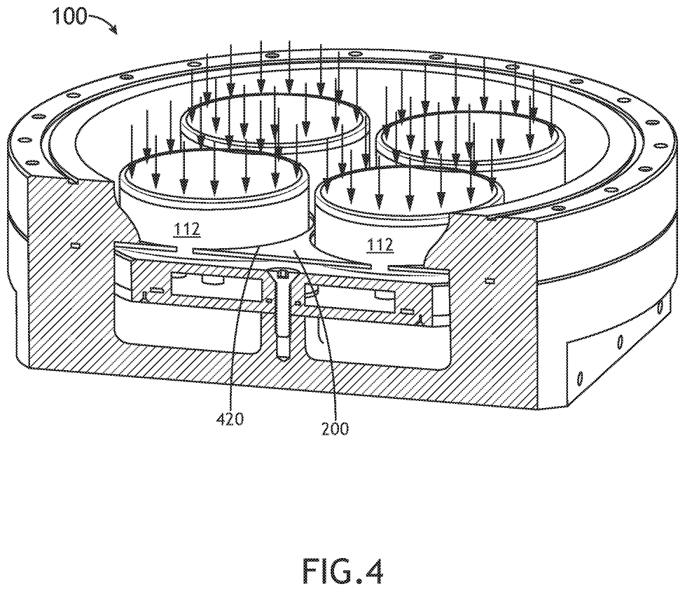

FIG. 4 illustrates a cross-sectional view of the system 100 with a large upper portion hidden for clarity, in accordance with one or more embodiments of the present disclosure.

In some embodiments, the gapped airflow modulator 200 may include a plate defining circular voids 420. The first set of gaps 250 may be defined as being between the circular voids 420 and the protrusions 112. For example, the gapped airflow modulator 200 may include a plate configured to fit inside the chamber 102 (e.g., via being circular, and may include, in the example shown, four circular voids 420 larger than the protrusions 112.

In some embodiments, the two or more protrusions 112 may include four protrusions 112 configured to hold four substrates 402.

FIG. 5 illustrates a cross-sectional view of the system 100 including an outlet 502, in accordance with one or more embodiments of the present disclosure.

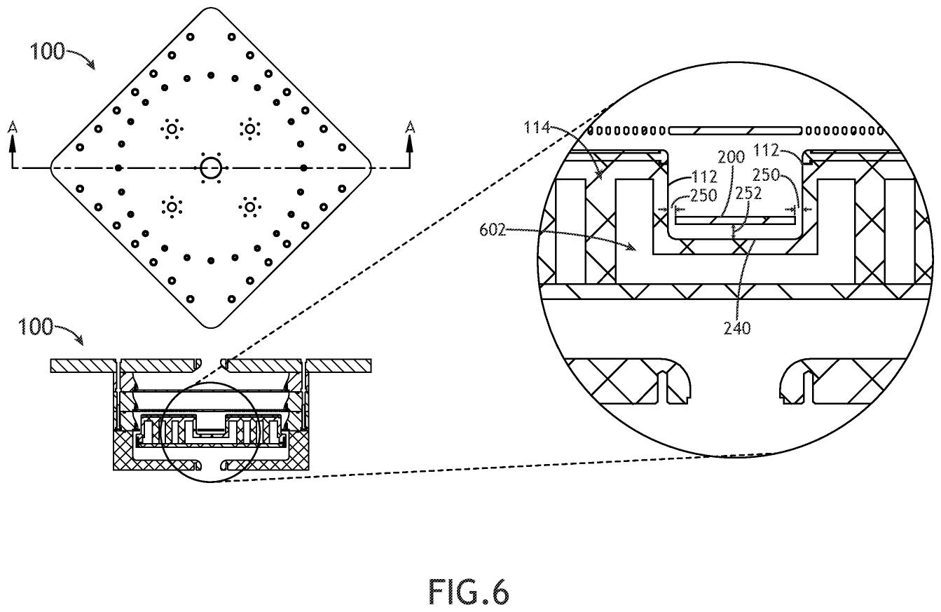

FIG. 6 illustrates a diagonally cut cross-sectional view of the system 100 with a portion enlarged showing gaps 250, 252 around (a middle portion of) the gapped airflow modulator 200, in accordance with one or more embodiments of the present disclosure.

In some embodiments, the protrusions may enclose an internal reservoir 602 configured to house temperature-controlling fluid for cooling the substrates 402 via indirect thermal communication with the temperature-controlling fluid. For example, the temperature-controlling fluid may include water and a coolant concentrate, a refrigerant, or the like.

The gaps 250, 252 may be any size that allows the plasma to flow below the gapped airflow modulator 200.

In some embodiments, the first set of gaps 250 may be 0.009 inches or more.

In some embodiments, the second gap 252 may be 0.02 inches or more.

In some embodiments, the first set of gaps 250 may be 0.1 inches or more.

In some embodiments, the second gap 252 may be 0.2 inches or more.

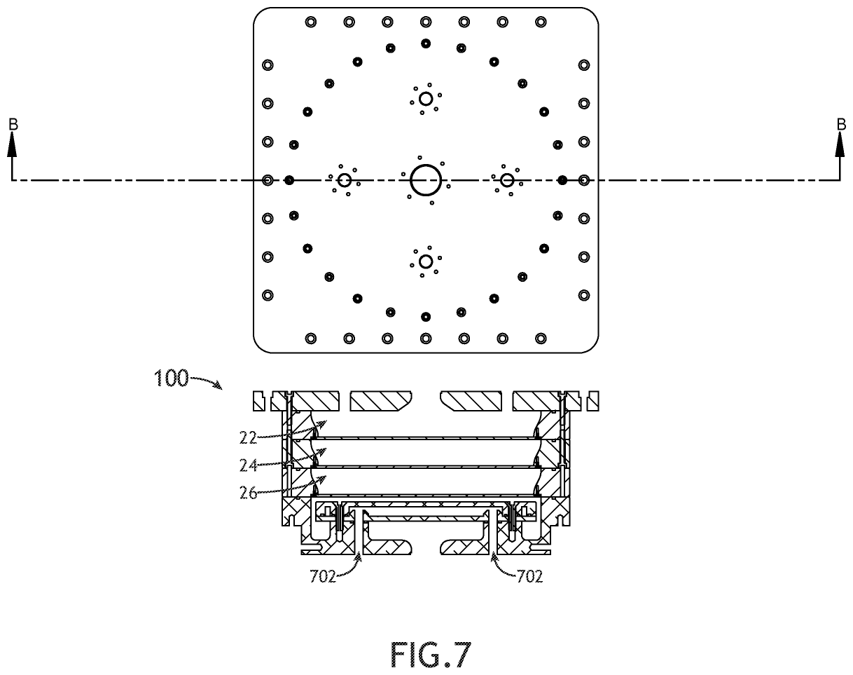

FIG. 7 illustrates a horizontally cut cross-sectional view of the system 100, in accordance with one or more embodiments of the present disclosure.

In some embodiments, the chamber 102, the support structure 114, and the gapped airflow modulator 200 may include (e.g., be made from) aluminum. For example, the gapped airflow modulator 200 may include aluminum.

The temperature-controlling fluid may be configured to be recirculated through the internal reservoirs 602 using one or more coolant inlets 702 or one or more coolant outlets 702.

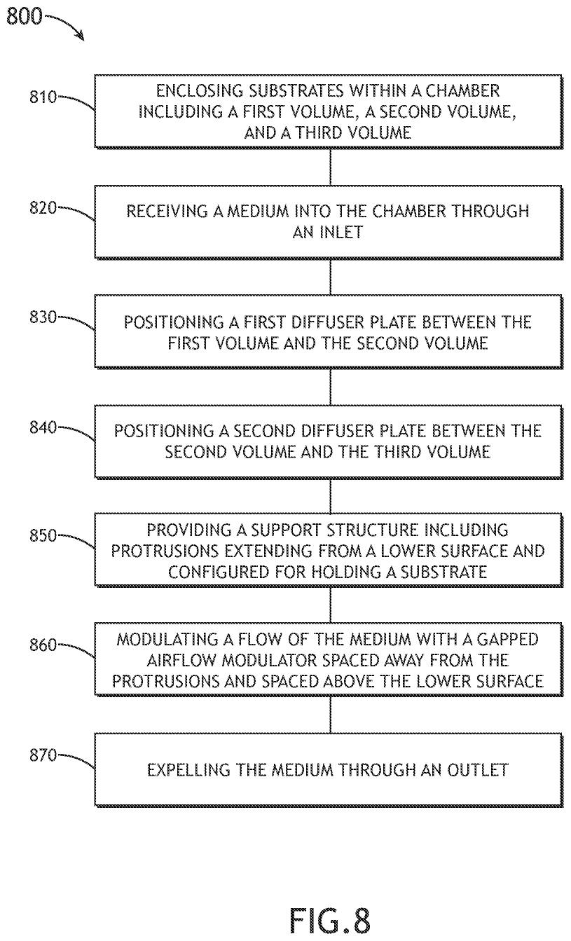

FIG. 8 is a method 800 for ashing substrates 402, in accordance with one or more embodiments of the present disclosure.

At step 810, substrates 402 are enclosed within a chamber 102 including a first volume 22, a second volume 24, and a third volume 26.

At step 820, a medium 10 is received into the chamber 102 through an inlet 110.

At step 830, a first diffuser plate 118 is positioned between the first volume 22 and the second volume 24 to split the medium 10 received from the inlet 110 into two or more pathways 116.

At step 840, a second diffuser plate 120 is positioned between the second volume 24 and the third volume 26 to facilitate targeted delivery of the medium 10 to the substrates 402.

At step 850, a support structure 114 is provided within the third volume 26, including two or more protrusions 112 extending from a lower surface 240 and configured for holding a substrate 402.

At step 860, a flow of the medium 10 is modulated (e.g., affected, contained, and/or directed in some way) with a gapped airflow modulator 200, which is spaced away from the two or more protrusions 112 via a first set of gaps 250 and spaced above the lower surface 240 via a second gap 252.

At step 870, the medium 10 is expelled from the chamber 102 through an outlet 502 after interacting with the substrates 402.

As used herein a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only and should not be construed to limit the disclosure in any way unless expressly stated to the contrary.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of “a” or “an” may be employed to describe elements and components of embodiments disclosed herein. This is done merely for convenience and “a” and “an” are intended to include “one” or “at least one,” and the singular also includes the plural unless it is obvious that it is meant otherwise.

Finally, as used herein any reference to “in embodiments”, “one embodiment” or “some embodiments” means that a particular element, feature, structure, or characteristic described in connection with the embodiment is included in at least one embodiment disclosed herein. The appearances of the phrase “in some embodiments” in various places in the specification are not necessarily all referring to the same embodiment, and embodiments may include one or more of the features expressly described or inherently present herein, or any combination or sub-combination of two or more such features, along with any other features which may not necessarily be expressly described or inherently present in the instant disclosure.

It is to be understood that embodiments of the methods disclosed herein may include one or more of the steps described herein. Further, such steps may be carried out in any desired order and two or more of the steps may be carried out simultaneously with one another. Two or more of the steps disclosed herein may be combined in a single step, and in some embodiments, one or more of the steps may be carried out as two or more sub-steps. Further, other steps or sub-steps may be carried in addition to, or as substitutes to one or more of the steps disclosed herein.

Although inventive concepts have been described with reference to the embodiments illustrated in the attached drawing figures, equivalents may be employed and substitutions made herein without departing from the scope of the claims. Components illustrated and described herein are merely examples of a system/device and components that may be used to implement embodiments of the inventive concepts and may be replaced with other devices and components without departing from the scope of the claims. Furthermore, any dimensions, degrees, and/or numerical ranges provided herein are to be understood as non-limiting examples unless otherwise specified in the claims.

What is claimed:

1. A system for ashing, the system comprising:
a chamber configured to enclose a substrate within a volume of the chamber and to process the substrate via a medium, wherein the volume comprises a first volume, a second volume, and a third volume, wherein the first volume is above the second volume and the second volume is above the third volume, wherein the chamber comprises:
an inlet configured for receiving the medium into the chamber, wherein the inlet is in fluid communication with the first volume; and
an outlet for expelling the medium after the medium has interacted with the substrate, wherein the outlet is in fluid communication with the third volume;
a first diffuser plate positioned between the first volume and the second volume and configured to split the medium received from the inlet into one or more pathways as it passes from the first volume to the second volume, the first diffuser plate being configured to allow selective transfer of the medium to the one or more pathways via one or more sets of first passthrough voids, each of the one or more pathways associated with a particular substrate and a respective set of first passthrough voids;
a second diffuser plate positioned between the second volume and the third volume, the second diffuser plate being configured to allow selective transfer of the medium along the one or more pathways to the substrate via one or more sets of second passthrough voids, each set of second passthrough voids being aligned with the respective set of first passthrough voids and a respective substrate to facilitate targeted delivery of the medium to the substrate;
a support structure within the third volume and coupled to the chamber, wherein the support structure comprises one or more protrusions extending from a lower surface towards the second diffuser plate, each protrusion configured for holding a single substrate; and
a gapped airflow modulator configured to modulate a flow of the medium, the gapped airflow modulator disposed between the one or more protrusions and lower than the substrate such that the gapped airflow modulator is further from the second diffuser plate than the substrate,
wherein the gapped airflow modulator is spaced away from the one or more protrusions via a first set of gaps, and spaced above the lower surface via a second gap.

2. The system of claim 1, wherein the system is configured for two or more substrates such that: the one or more pathways comprises two or more pathways, the one or more sets of first passthrough voids comprise two or more sets of first passthrough voids, the one or more sets of second passthrough voids comprise two or more sets of second passthrough voids, and the one or more protrusions comprise two or more protrusions.

3. The system of claim 1, wherein the gapped airflow modulator comprises a plate defining circular voids, wherein the first set of gaps are defined as being between the circular voids and the one or more protrusions.

4. The system of claim 1, wherein the one or more sets of first passthrough voids are larger in diameter than the one or more sets of second passthrough voids.

5. The system of claim 1, wherein the one or more protrusions comprise four protrusions configured to hold four substrates.

6. The system of claim 1, wherein the support structure is removably couplable to the chamber.

7. The system of claim 1, wherein the chamber, the support structure, and the gapped airflow modulator comprise aluminum.

8. The system of claim 1, wherein the one or more protrusions enclose an internal reservoir configured to house temperature-controlling fluid for cooling the substrate via indirect thermal communication with the temperature-controlling fluid.

9. The system of claim 1, wherein each protrusion comprises an elevated cylindrical platform.

10. The system of claim 1, wherein the medium comprises ionized plasma.

11. The system of claim 1, wherein the first set of gaps are 0.009 inches or more.

12. The system of claim 1, wherein the second gap is 0.02 inches or more.

13. The system of claim 1, wherein the first set of gaps are 0.1 inches or more.

14. The system of claim 1, wherein the second gap is 0.2 inches or more.

15. A method for ashing comprising:
enclosing substrate within a volume of a chamber of a system, wherein the volume comprises a first volume, a second volume, and a third volume, wherein the first volume is above the second volume and the second volume is above the third volume;
receiving a medium into the chamber through an inlet in fluid communication with the first volume;
positioning a first diffuser plate between the first volume and the second volume to split the medium received from the inlet into one or more pathways as it passes from the first volume to the second volume, wherein the first diffuser plate allows selective transfer of the medium to the one or more pathways via one or more sets of first passthrough voids, each pathway associated with a particular substrate and a respective set of first passthrough voids;
positioning a second diffuser plate between the second volume and the third volume to allow selective transfer of the medium along the one or more pathways to the substrate via one or more sets of second passthrough voids, each set of second passthrough voids being aligned with the respective set of first passthrough voids and a respective substrate to facilitate targeted delivery of the medium to the substrate;
providing a support structure within the third volume and coupled to the chamber, wherein the support structure comprises one or more protrusions extending from a lower surface towards the second diffuser plate, each protrusion configured for holding a single substrate;
modulating a flow of the medium with a gapped airflow modulator disposed between the one or more protrusions and lower than the substrate such that the gapped airflow modulator is further from the second diffuser plate than the substrate, wherein the gapped airflow modulator is spaced away from the one or more protrusions via a first set of gaps, and spaced above the lower surface via a second gap; and
expelling the medium after interaction with the substrate through an outlet in fluid communication with the third volume.

16. The method of claim 15, wherein the system is configured for two or more substrates such that: the one or more pathways comprises two or more pathways, the one or more sets of first passthrough voids comprise two or more sets of first passthrough voids, the one or more sets of second passthrough voids comprise two or more sets of second passthrough voids, and the one or more protrusions comprise two or more protrusions.

17. The method of claim 15, wherein the gapped airflow modulator comprises a plate defining circular voids, and the first set of gaps are defined as being between the circular voids and the one or more protrusions.

18. The method of claim 15, wherein the one or more sets of first passthrough voids are larger in diameter than the one or more sets of second passthrough voids.

19. The method of claim 15 further comprising removably coupling the support structure to the chamber.

20. The method of claim 15, wherein the one or more protrusions enclose an internal reservoir configured to house temperature-controlling fluid for cooling the substrate via indirect thermal communication with the temperature-controlling fluid.
